(19) United States
(12) Patent Application Publication
(10) Pub. No.: US 2014/0160645 A1
(43) Pub. Date: Jun. 12, 2014

(54) ELECTRONIC DEVICE

(71) Applicants: FU TAI HUA INDUSTRY (SHENZHEN) CO., LTD., Shenzhen (CN); HON HAI PRECISION INDUSTRY CO., LTD., New Taipei (TW)

(72) Inventor: ZHAN-SHENG LU, Shenzhen (CN)

(73) Assignees: HON HAI PRECISION INDUSTRY CO., LTD., New Taipei (TW); FU TAI HUA INDUSTRY (SHENZHEN) CO., LTD., Shenzhen (CN)

(21) Appl. No.: 13/868,113

(22) Filed: Apr. 23, 2013

(30) Foreign Application Priority Data
Dec. 12, 2012 (CN) 2012105333149

(51) Int. Cl. H05K 5/02; H05K 5/03

(52) U.S. Cl. CPC H05K 5/0217; H05K 5/03
USPC 361/679.01

(57) ABSTRACT

An electronic device is provided. The electronic device includes a top cover, a first magnet and a second magnet, a first adhesive element and a second adhesive element, and a bottom cover. The first adhesive element adheres the first magnet to the top cover. The bottom cover includes a bottom panel, a sidewall extending from a periphery of the bottom panel, and a protruding rim extending inwards from the sidewall. The second adhesive element sticks the second magnet to the protruding rim. The first magnet is magnetically attached to the second magnet. Therefore, the top cover, the first and the second magnets, and the sidewall of the bottom cover are firmly held together to present an apparently seamless connection between the top cover and the bottom cover.

### BACKGROUND

1. Technical Field

The disclosure relates to an electronic device and, more particularly, to an electronic device for presenting a seamless connection between a top cover and a bottom cover thereof.

2. Description of Related Art

Screws are often used between a top cover and a bottom cover of an electronic device, but the presence of screws, even if capped, is obvious, spoiling the aesthetic appeal of the device.

Therefore, what is needed is an electronic device to overcome the described shortcoming.

### BRIEF DESCRIPTION OF THE DRAWINGS

FIG. 1 is a perspective view of an electronic device in accordance with an exemplary embodiment.

FIG. 2 is an exploded view of the electronic device of FIG. 1.

FIG. 3 is a partially enlarged view of a bottom cover of the electronic device of FIG. 2.

FIG. 4 is a sectional view of the electronic device of FIG. 1.

### DETAILED DESCRIPTION

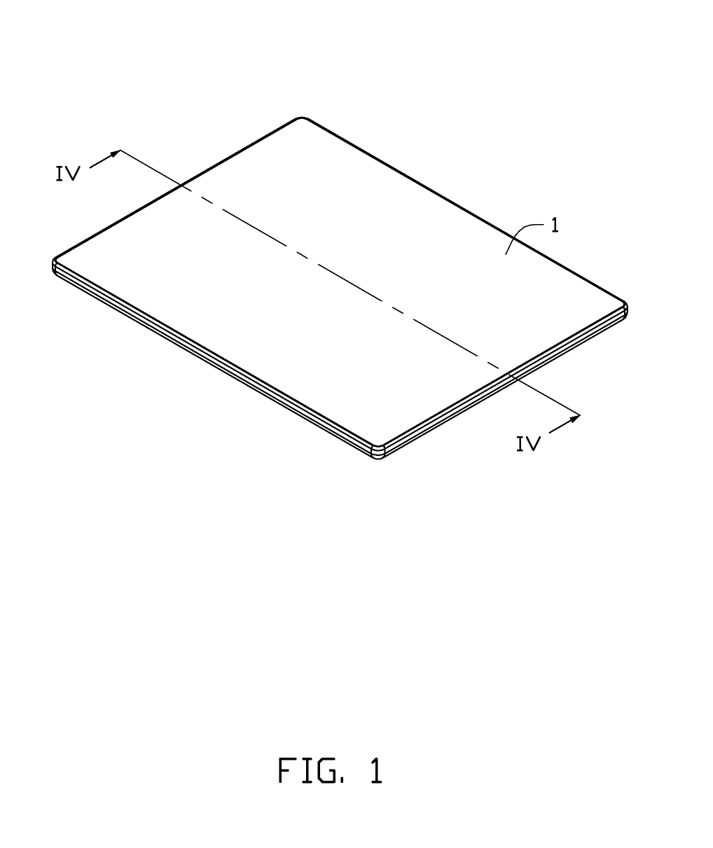

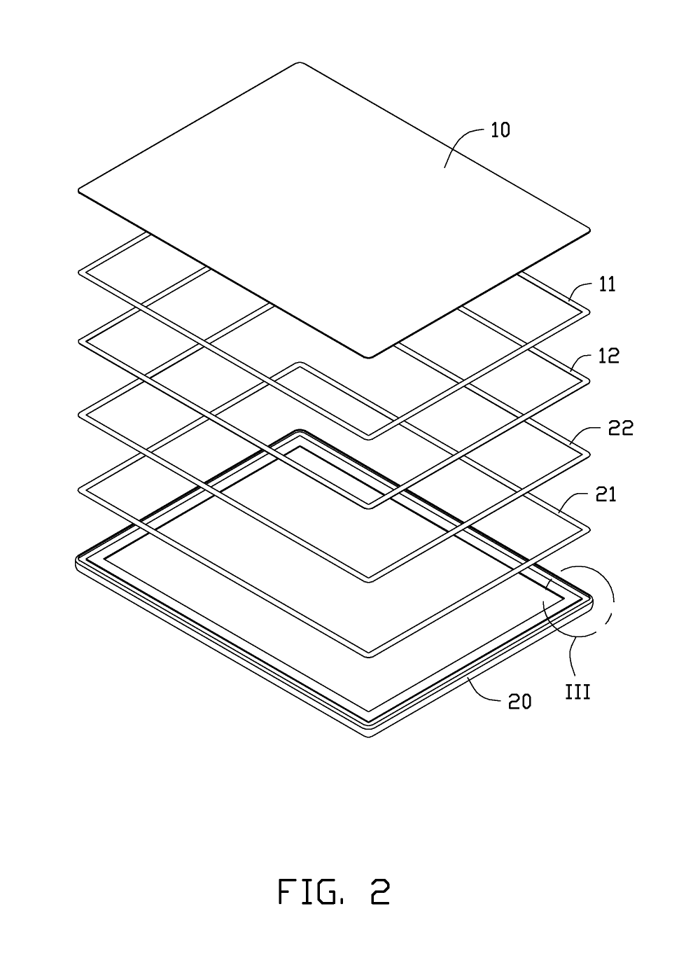

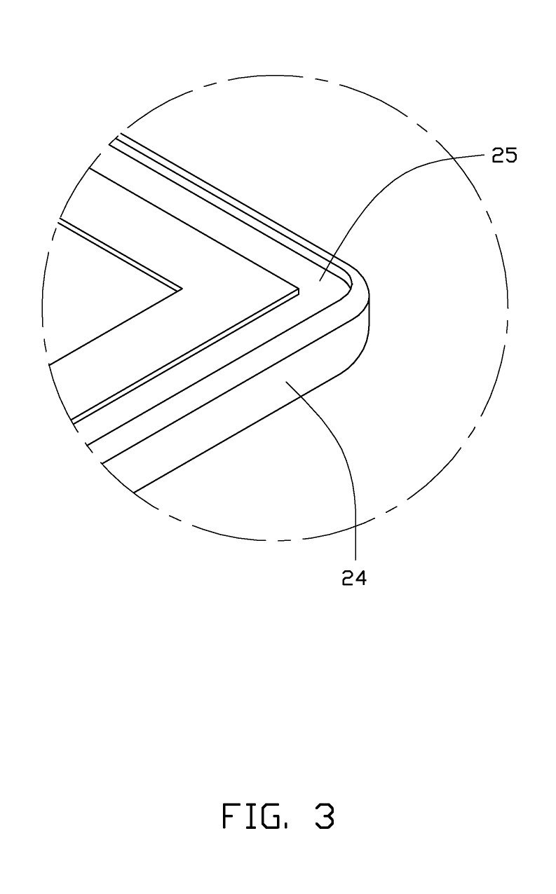

FIGS. 1-3 show an electronic device 1 of one embodiment. The electronic device 1 may be a mobile phone or a tablet computer. The electronic device 1 includes a top cover 10, a first adhesive element 11, a first magnet 12, a bottom cover 20, a second adhesive element 21, and a second magnet 22. The top cover 10 is a flat panel. The top cover 10 is made of transparent glass; therefore, a user can look at contents displayed on a screen (not shown) of the electronic device 1 under the top cover 10. The first adhesive element 11, the first magnet 12, the bottom cover 20, and the second adhesive element 21 are loop-shaped.

The first adhesive element 11 adheres the first magnet 12 to the top cover 10. For example, the first adhesive element 11 is a loop-shaped double-sided adhesive tape. A width of the first adhesive element 11 is equal to a width of the first magnet 12.

The bottom cover 20 includes a bottom panel 23 and a sidewall 24 extending from a periphery of the bottom panel 23. A protruding rim 25 extends inwards from the sidewall 24. In the embodiment, the protruding rim 25 perpendicularly extends from the sidewall 24. The second adhesive element 21 adheres the second magnet 22 to the protruding rim 25. For example, the second adhesive element 21 is a loop-shaped double-sided adhesive tape. A width of the second adhesive element 21 is equal to a width of the second magnet 22. In the embodiment, both the first magnet 12 and the second magnet 22 have a same configuration.

When in use, the first magnet 12 is magnetically attached to the second magnet 22, that means that one pole of the first magnet 12 faces the opposite pole of the second magnet 22, for example, a north pole of the first magnet 12 faces down and a south pole of the second magnet 22 faces up, and different poles of the first and the second magnets 12, 22 attract, therefore, both the first and the second magnets 12, 22 cling tightly to each other.

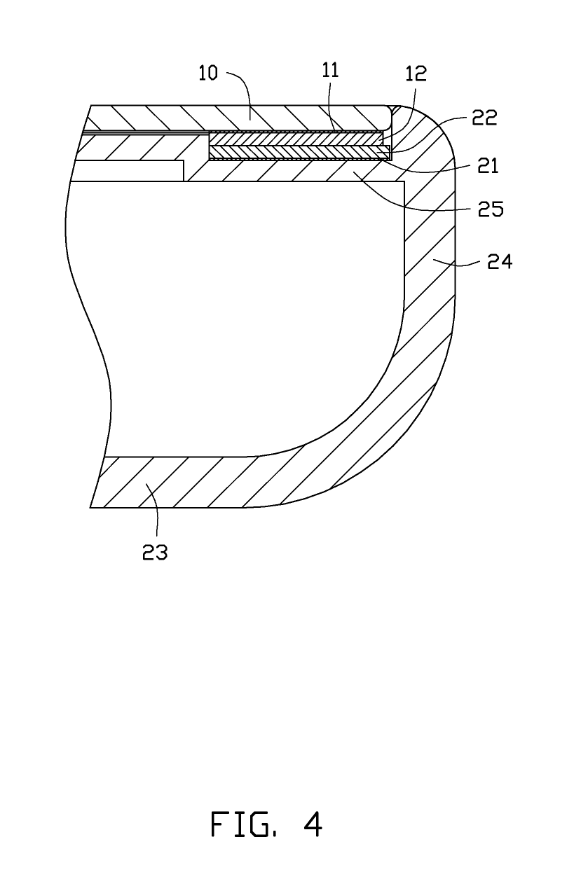

FIG. 4 shows that when the top cover 10 is assembled with the bottom cover 20, the top cover 10 carries the first magnet 12 via the first adhesive element 11, the protruding rim 25 of the bottom cover 20 carries the second magnet 22 via the second adhesive element 21, and both the first and the second magnets 12, 22 tightly abut each other. In addition, all peripheral surfaces of the top cover 10 contact all inner surfaces of the sidewall 24 of the bottom cover 20. Therefore, the top cover 10, the first and the second magnets 12, 22, and the sidewall 24 of the bottom cover 20 adhere to each other to present an apparently seamless connection between the top cover 10 and the bottom cover 20.

Although the present disclosure has been specifically described on the basis of the exemplary embodiment thereof, the disclosure is not to be construed as being limited thereto. Various changes or modifications may be made to the embodiment without departing from the scope and spirit of the disclosure.

What is claimed is:

1. An electronic device comprising:
a top cover;
a first loop-shaped magnet and a second loop-shaped magnet;
a first loop-shaped adhesive element adhering the first magnet to the top cover;
a bottom cover comprising a bottom panel, a sidewall extending from a periphery of the bottom panel, and a protruding rim extending inwards from the sidewall;
a second loop-shaped adhesive element adhering the second magnet to the protruding rim; and
wherein the first magnet is magnetically attached to the second magnet.

2. The electronic device as recited in claim 1, wherein the top cover is a flat panel.

3. The electronic device as recited in claim 1, wherein a width of the first adhesive element is equal to a width of the first magnet.

4. The electronic device as recited in claim 1, wherein the first adhesive element is a loop-shaped double-sided adhesive tape.

5. The electronic device as recited in claim 1, wherein the protruding rim perpendicularly extends from the sidewall.

6. The electronic device as recited in claim 1, wherein a width of the second adhesive element is equal to a width of the second magnet.

7. The electronic device as recited in claim 1, wherein the second adhesive element is a loop-shaped double-sided adhesive tape.

8. The electronic device as recited in claim 1, wherein both the first magnet and the second magnet have a same configuration.

9. The electronic device as recited in claim 1, wherein all peripheral surfaces of the top cover contact all inner surfaces of the sidewall of the bottom cover.
